(19) United States
(12) Patent Application Publication
(10) Pub. No.: US 2025/0295039 A1
(43) Pub. Date: Sep. 18, 2025

(54) Tunnel Magneto-Resistive Sensor With Thin Nonmagnetic Material In Free Layer

(71) Applicant: Headway Technologies, Inc., Milpitas, CA (US)

(72) Inventors: Hui-Chuan Wang, Pleasanton, CA (US); Shohei Kawasaki, Sunnyvale, CA (US); Kunliang Zhang, Fremont, CA (US); Zheng Gao, San Jose, CA (US); Sangmun Oh, San Jose, CA (US); Huadong Gan, Union City, CA (US)

(21) Appl. No.: 18/608,520

(22) Filed: Mar. 18, 2024

(51) Int. Cl. H10N 50/10; G01R 33/09; G11B 5/39; H10N 50/01; H10N 50/85

(52) U.S. Cl. CPC H10N 50/10; G01R 33/093; G01R 33/098; G11B 5/3909; H10N 50/01; H10N 50/85

(57) ABSTRACT

The present embodiments relate to a free layer structure of a sensor (e.g., a tunneling magneto-resistive (TMR) sensor) with a non-magnetic layer deposited between free layers. For instance, a free layer structure can be created by inserting a subatomic non-magnetic layer with materials such as Tantalum (Ta) or Hafnium (Hf) between a first free layer and a second free layer. Inserting the non-magnetic layer can break the translation of the first free layer crystalline structure to the second free layer, thus making the second free layer more amorphous. The free layer structure can also include inserting an insertion layer before depositing a capping layer, which can reduce the influence of the capping layer crystalline structure to the free layer. Another example free layer structure can include inserting both the non-magnetic layer and the insertion layer to obtain a magnetically softer film.

### TECHNICAL FIELD

Embodiments of the invention relate to the field of electro-mechanical data storage devices. More particularly, embodiments of the invention relate to a free layer structure of a tunneling magneto-resistive (TMR) sensor comprising a non-magnetic material deposited between free layers.

### BACKGROUND

A magnetic recording medium (e.g., a magnetic disk) can store magnetic bits representing digital data. A magneto-resistive writer can be part of a hard disk drive (HDD) to write digital data to the magnetic recording medium.

As an overall amount of digital data being stored on HDD devices increases, there is an increasing demand for increased data capacity of HDD devices. One technique to increase data capacity for an HDD can include heat-assisted magnetic recording (HAMR) or microwave-assisted magnetic recording (MAMR). HAMR and MAMR techniques increase the density of HDDs by manipulating a portion of the magnetic recording medium, which can enhance write performance of the write head to the magnetic recording medium.

Further, tunneling magneto-resistive (TMR) sensors with stable shield biasing can be important for various high density magnetic recording applications. The TMR sensor can include any of a free layer, barrier layer, and a pin layer. The magnetization direction of the pin layer can be configured to be fixed and a magnetization direction of the free layer can change due to an external magnetic field direction. Further, an electrical resistance of the TMR sensor can decrease when magnetization directions of the pin layer and free layer are in parallel, and the electrical resistance of the TMR sensor can increase when magnetization directions of the pin layer and free layer are anti-parallel.

### SUMMARY

The present embodiments relate to a free layer structure of a sensor (e.g., a tunneling magneto-resistive (TMR) sensor) with a non-magnetic layer deposited between free layers. For instance, a free layer structure can be created by inserting a subatomic non-magnetic layer with materials such as Tantalum (Ta) or Hafnium (Hf) between a first free layer and a second free layer. Inserting the non-magnetic layer can break the translation of the first free layer crystalline structure to the second free layer, thus making the second free layer more amorphous. The free layer structure can also include inserting an insertion layer before depositing a capping layer, which can reduce the influence of the capping layer crystalline structure to the free layer. Another example free layer structure can include inserting both the non-magnetic layer and the insertion layer to obtain a magnetically softer film.

In a first example embodiment, a free layer structure for a tunneling magneto-resistive (TMR) sensor is provided. The free layer structure can include a first free layer, a second free layer, and a non-magnetic layer deposited between the first free layer and the second free layer. The free layer structure can be anisotropic and can achieve low Hc, high moment, and high dR/R.

In some instances, the first free layer comprises a Cobalt-Iron-Boron (CoFeB) alloy.

In some instances, the second free layer comprises a Cobalt-Iron-Tantalum (CoFeTa) alloy or a Cobalt-Iron-Hafnium (CoFeHf) alloy.

In some instances, the non-magnetic layer comprises any of Hafnium (Hf), Tantalum (Ta), Yttrium (Y), Niobium (Nb), Molybdenum (Mo), Tungsten (W), and Titanium (Ti).

In some instances, a thickness of the non-magnetic layer is less than 2 Angstroms (A) or ranging between 0.2 and 2.5 A.

In some instances, the free layer structure can further include an insertion layer deposited adjacent to the first free layer and a capping layer deposited over the insertion layer. The insertion layer can be configured to reduce an influence of a crystalline structure of the capping layer to the first free layer.

In some instances, the insertion layer comprises any of Hf, Ta, Y, Zr, Nb, Mo, W, Ti. A thickness of the insertion layer can be less than 5 A or ranging between 1 to 5 A.

In some instances, the capping layer comprises Ruthenium (Ru).

In some instances, the first free layer comprises CoFe-xB-y or CoFe-aHf-b, where x is between 10-70 percent of the material (at %), wherein y is between 5-30 at %, a is between 10-70 at %, and wherein b is between 2-20 at %.

In some instances, the free layer structure is configured to be deposited adjacent to a barrier layer that is adjacent to a pin layer. A magnetization direction of the pin layer can be configured to be fixed and a magnetization direction of the free layer is configured to change due to an external magnetic field direction. The barrier layer can be configured to include any of magnesium oxide (MgO), aluminum oxide (AlOx), titanium oxide (TiOx), and/or zinc oxide (ZnOx).

In another example embodiment, a device is provided. The device can include a free layer structure that includes a first free layer, a second free layer, and a non-magnetic layer deposited between the first free layer and the second free layer. The device can also include an insertion layer deposited adjacent to the first free layer, and a capping layer deposited over the insertion layer. The insertion layer can be configured to reduce an influence of a crystalline structure of the capping layer to the first free layer.

In some instances, the first free layer comprises a Cobalt-Iron-Boron (CoFeB) alloy. The second free layer can include a Cobalt-Iron-Tantalum (CoFeTa) alloy or a Cobalt-Iron-Hafnium (CoFeHf) alloy.

In some instances, the non-magnetic layer and the insertion layer comprises any of Hafnium (Hf), Tantalum (Ta), Yttrium (Y), Niobium (Nb), Molybdenum (Mo), Tungsten (W), and Titanium (Ti).

In some instances, a thickness of the non-magnetic layer is less than 2 Angstroms (A) or ranging between 0.2 and 2.5 A. A thickness of the insertion layer can be less than 5 A or ranging between 1 to 5 A.

In some instances, the capping layer comprises Ruthenium (Ru).

In some instances, the first free layer comprises CoFe-xB-y or CoFe-aHf-b, where x is between 10-70 percent of the material (at %), wherein y is between 5-30 at %, a is between 10-70 at %, and wherein b is between 2-20 at %.

In some instances, the free layer structure is configured to be deposited adjacent to a barrier layer that is adjacent to a pin layer. A magnetization direction of the pin layer can be configured to be fixed and a magnetization direction of the free layer is configured to change due to an external magnetic field direction. The barrier layer can be configured to include any of magnesium oxide (MgO), aluminum oxide (AlOx), titanium oxide (TiOx), and/or zinc oxide (ZnOx).

In another example embodiment, a method of manufacturing a free layer structure for a tunneling magneto-resistive (TMR) sensor is provided. The method can include depositing a non-magnetic layer between a first free layer and a second free layer. The non-magnetic layer can include Tantalum (Ta) or Hafnium (Hf). The first free layer and second free layer can include any of a Cobalt-Iron-Boron (CoFeB) alloy, a Cobalt-Iron-Tantalum (CoFeTa) alloy, and a Cobalt-Iron-Hafnium (CoFeHf) alloy. The method can also include depositing a barrier layer adjacent to the free layer structure. The method can also include depositing a pin layer adjacent to the barrier layer.

In some instances, the method can also include depositing an insertion layer adjacent to the first free layer and depositing a capping layer deposited over the insertion layer. The insertion layer can be configured to reduce an influence of a crystalline structure of the capping layer to the first free layer.

In some instances, the insertion layer comprises any of Hf, Ta, Y, Zr, Nb, Mo, W, Ti, and wherein a thickness of the insertion layer is less than 5 A or ranging between 1 to 5 A.

Other features and advantages of embodiments of the present invention will be apparent from the accompanying drawings and from the detailed description that follows.

### BRIEF DESCRIPTION OF THE DRAWINGS

Embodiments of the present invention are illustrated by way of example and not limitation in the figures of the accompanying drawings, in which like references indicate similar elements and in which:

FIG. 1 is a perspective view of a head arm assembly, according to prior art embodiments.

FIG. 2 is side view of a head stack assembly, according to prior art embodiments.

FIG. 3 is a plan view of a magnetic recording apparatus, according to prior art embodiments.

FIG. 4 illustrates an example TMR sensor according to an embodiment.

FIG. 5 is an illustration of a first example free layer structure according to an embodiment.

FIG. 6 is an illustration of a second example free layer structure according to an embodiment.

FIG. 7 is an illustration of a third example free layer structure according to an embodiment.

### DETAILED DESCRIPTION

A disk drive can include a write head to interact with a magnetic recording medium to read and write digital data to the magnetic recording medium. As the amount of digital data is required to be stored increases and with an increase in data aerial density of hard disk drive (HDD) writing, both the write head and digital data written to the magnetic recording medium can generally be made smaller.

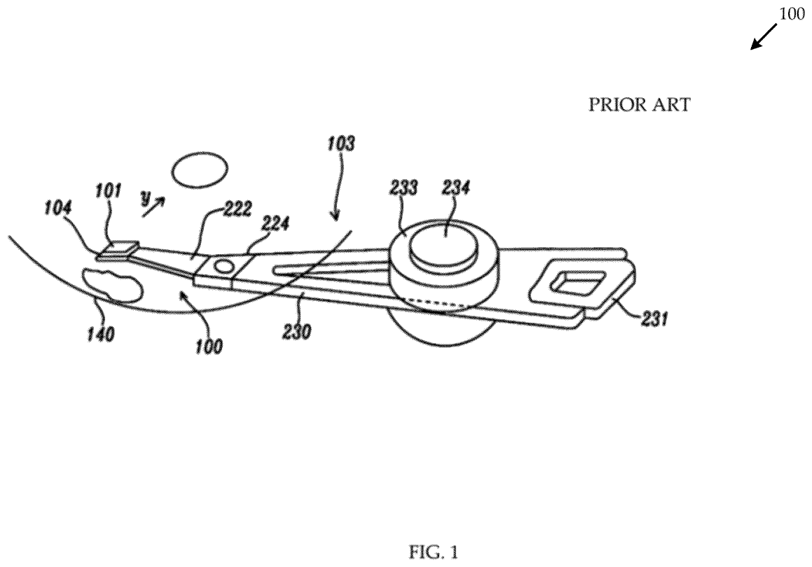

FIG. 1 is a perspective view of a prior art head arm assembly 100, according to some embodiments of the present disclosure. Referring to FIG. 1, a head arm assembly (or Head Gimbal Assembly (HGA)) 100 includes a magnetic recording head 101 comprised of a slider and a PMR writer structure formed thereon, and a suspension 103 that elastically supports the magnetic recording head. The suspension has a plate spring-like load beam 222 formed with stainless steel, a flexure 104 provided at one end portion of the load beam, and a base plate 224 provided at the other end portion of the load beam. The slider portion of the magnetic recording head is joined to the flexure, which gives an appropriate degree of freedom to the magnetic recording head. A gimbal part (not shown) for maintaining a posture of the magnetic recording head at a steady level is provided in a portion of the flexure to which the slider is mounted.

HGA 100 is mounted on an arm 230 formed in the head arm assembly 103. The arm moves the magnetic recording head 101 in the cross-track direction y of the magnetic recording medium 140. One end of the arm is mounted on base plate 224. A coil 231 that is a portion of a voice coil motor is mounted on the other end of the arm. A bearing part 233 is provided in the intermediate portion of arm 230. The arm is rotatably supported using a shaft 234 mounted to the bearing part 233. The arm 230 and the voice coil motor that drives the arm configure an actuator.

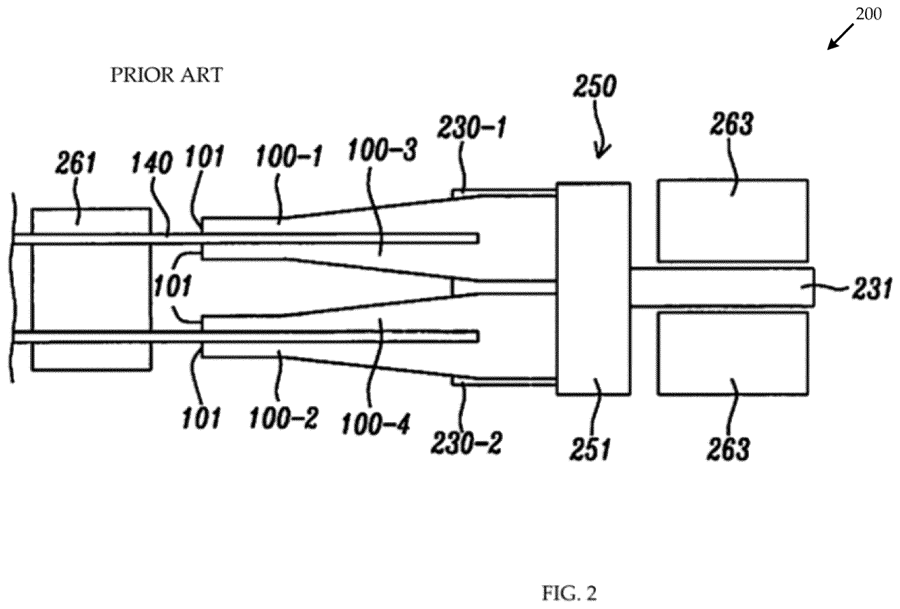

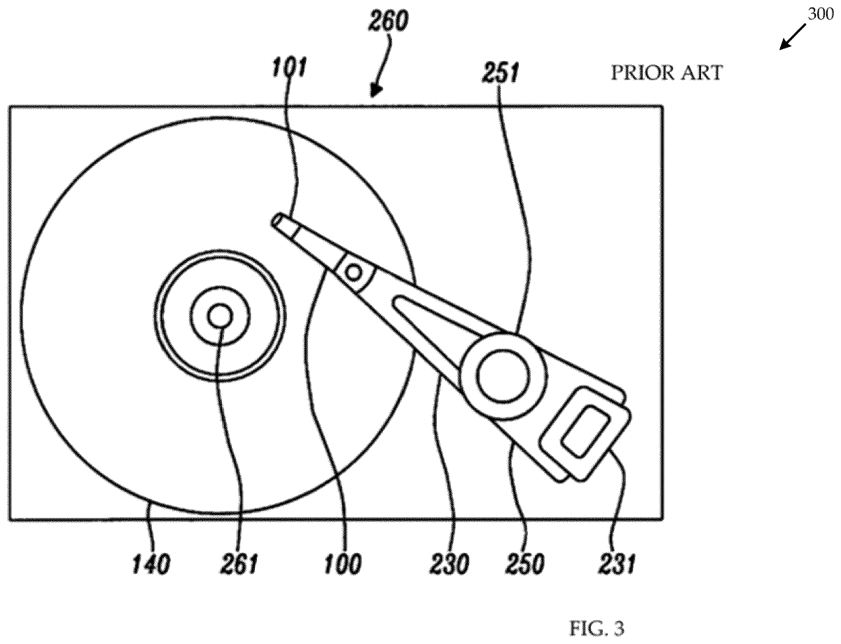

Next, a side view 200 of a head stack assembly (FIG. 2) and a plan view 300 of a magnetic recording apparatus (FIG. 3) wherein the magnetic recording head 101 is incorporated are depicted. The head stack assembly 250 is a member to which a plurality of HGAs (HGA 100-1 and second HGA 100-2 are at outer positions while HGA 100-3 and HGA 100-4 are at inner positions) is mounted to arms 230-1, 230-2, respectively, on carriage 251. A HGA is mounted on each arm at intervals so as to be aligned in the perpendicular direction (orthogonal to magnetic medium 140). The coil portion (231 in FIG. 1) of the voice coil motor is mounted at the opposite side of each arm in carriage 251. The voice coil motor has a permanent magnet 263 arranged at an opposite position across the coil 231.

With reference to FIG. 3, the head stack assembly 250 is incorporated in a magnetic recording apparatus 260. The magnetic recording apparatus has a plurality of magnetic media 140 mounted to spindle motor 261. For every magnetic recording medium, there are two magnetic recording heads arranged opposite one another across the magnetic recording medium. The head stack assembly and actuator except for the magnetic recording heads 101 correspond to a positioning device, and support the magnetic recording heads, and position the magnetic recording heads relative to the magnetic recording medium. The magnetic recording heads are moved in a cross-track of the magnetic recording medium by the actuator. The magnetic recording head records information into the magnetic recording media with a PMR writer element (not shown) and reproduces the information recorded in the magnetic recording media by a magneto-resistive (MR) sensor element (not shown).

Further, tunneling magneto-resistive (TMR) sensors with stable shield biasing can be important for various high density magnetic recording applications. Particularly, a shield material as described herein, such as a cobalt-iron (CoFe) and Tantalum (Ta) (CFT) shield, can have a high magnetic moment and an amorphous structure can be used as part of a shield layer.

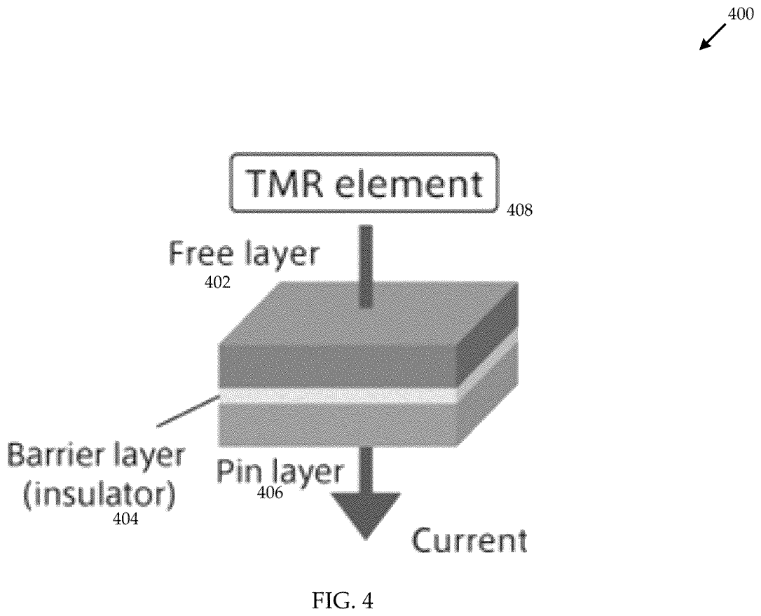

FIG. 4 illustrates an example TMR sensor 400. As shown in FIG. 4, the TMR sensor 400 can include a free layer 402, a barrier layer 404, and a pin layer 406. The free layer 402 can include a soft magnetic material as described herein. A barrier layer 404 can be deposited between the free layer 402 and pin layer 406. The barrier layer can be made of a thin insulator of 1 to 2 nm and can be sandwiched between two ferromagnetic layers (e.g., the free layer and pin layer).

The electrical resistance of the TMR element 408 can change along with a change in the free layer 402. The electrical resistance can become the smallest when the magnetization directions of the pin layer 406 and free layer 402 are parallel, causing a large current to flow into the barrier layer 404. When the magnetization directions are antiparallel, the resistance can become extremely large, and almost no current may flow into the barrier layer 404.

TMR sensors with thin, magnetically soft, and high flux free layers can be used in many next-generation magnetic recording applications. High flux free layers tend to provide large magnetic moments, which can enable the TMR film stack to be thinned while improving device performance. Cobalt-Iron-Boron (CoFeB) and Cobalt-Iron (CoFe) alloys can be candidate materials responsive to identifying ways to reduce coercivity (Hc) while maintaining their high magnetic moments (Bst).

A potential drawback of high flux CoFe alloys is that they may have higher coercivity (Hc), which can make the free layer magnetically harder and less sensitive than what can be expected in many applications. In some instances, tantalum (Ta) or hafnium (Hf) can be added as a dopant to CoFe alloys. By adjusting the power ratio between the co-sputtered CoFe and the dopant (Ta or Hf), both amorphous CoFeTa and CoFeHf devices with a high magnetic flux density (Bst) (>2.0 nano weber (nWb)), low coercive magnetic field strength (Hc) (<4 Oersted (Oe)), and a high magnetoresistance (MR) ratio (change of resistivity (dR/R)>120% at RA0.3) can be obtained.

To further improve the CoFeB or CoFeTa (or CoFeHf) free layer magnetic properties, the present embodiments relate to at least three types of free layer structures. As described in greater detail below, the Hc can be further reduced with a trade-off in Bst. A first structure can be created by inserting a subatomic nonmagnetic layer such as Ta or Hf between CoFeB (a first free layer and the textured film (e.g., a crystal structure) can be required to generate MR signal) and CoFeHf or CoFeTa (the second free layer and the amorphous film can ensure the material is magnetically soft and has high μ, small grain size, and high flux). Inserting the subatomic Ta or Hf in between the first free layer and the second free layer can break the translation of free layer 1 crystalline structure to the second free layer, thus making the second free layer (CoFeTa or CoFeHf) more amorphous. As a result, the layer can have a low Hc (<4 Oe), and high Bst (>2.0 nWb).

A second example design can include applying a similar concept to insert a thin Ta or Hf before the capping layer deposition, which can reduce the influence of Ru crystalline structure to the free layer. As a result, a low Hc (<4 Oe), and high Bst (>2.0 nWb), free layer can be achieved.

A third example design can include combining both the first example design and the second example design to obtain a magnetically softer film.

In some instances, a free layer structure as described herein can include a CoFeB/CoFeHf free layer with a thin insertion layer. The free layer structure can be anisotropic and has low Hc (<4 Oe), high moment (Bst>2.0 nWb), and high MR ratio (dR/R>120% at RA 0.3).

Any of Hf, Ta, Yttrium (Y), Zirconium (Zr), Niobium (Nb), Molybdenum (Mo), Tungsten (W), Titanium (Ti), etc., can be used as the insertion layer. The thickness of the insertion layer can range from 0.2˜2.5 Angstroms (A). The thickness of the insertion layer can range from 1˜5 A. The free layer structure can be CoFe-xB-y/CoFe-aHf-b where x=10˜70 at %, y=5˜30 at %, a=10˜70 at %, b=2˜20 at %. The free layer structure can be CoFe-xB-y/CoFe-aTa-b where x=10˜70 at %, y=5˜30 at %, a=10˜70 at %, b=2˜20 at %. The free layer could be used for TMR sensors with magnesium oxide (MgO), aluminum oxide (AlOx), titanium oxide (TiOx), zinc oxide (ZnOx) barriers.

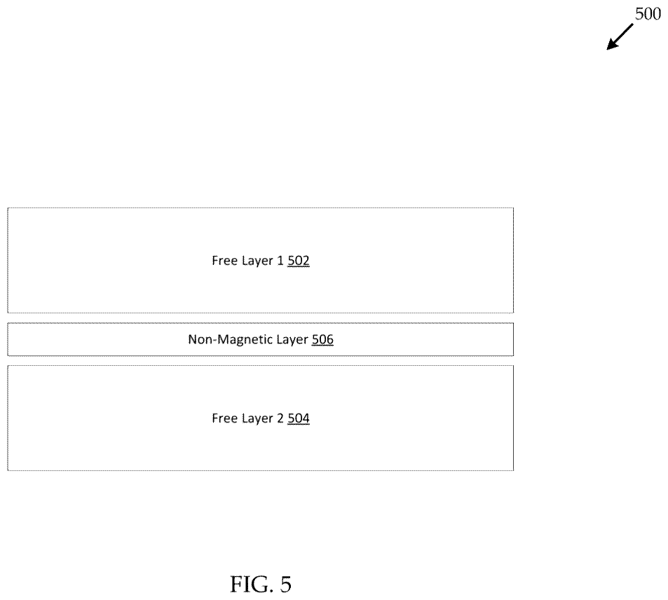

FIG. 5 is an illustration 500 of a first example free layer structure. As shown in FIG. 5, the free layer structure 500 can include a first free layer 502, a second free layer 504, and a non-magnetic layer 506. A first free layer 502 can include CoFeB (or CoFeHf or CoFeTa), while the second free layer 504 can include CoFeHf or CoFeTa (or CoFeB). The non-magnetic layer 506 can include a subatomic nonmagnetic material such as Ta or Hf with a thickness of less than 2 A.

The first free layer and a textured film (e.g., a crystal structure) can be used to generate MR signal, while the second free layer and the amorphous film can ensure the material is magnetically soft and has high μ, small grain size, and high flux.

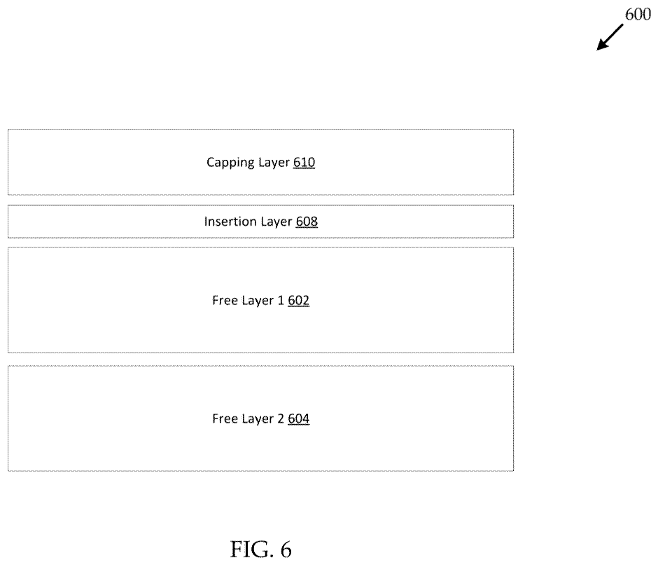

FIG. 6 is an illustration 600 of a second example free layer structure. As shown in FIG. 6, an insertion layer 608 can be deposited between a free layer (e.g., first free layer 602) and a capping layer 610. The insertion layer 608 can include a thin Ta or Hf layer of less than 5 A. The capping layer 610 can include a material such as Ruthenium (Ru). The insertion layer 608 can be deposited on the free layer 602 prior to depositing the capping layer 610, which can reduce the influence of Ru crystalline structure to the free layer.

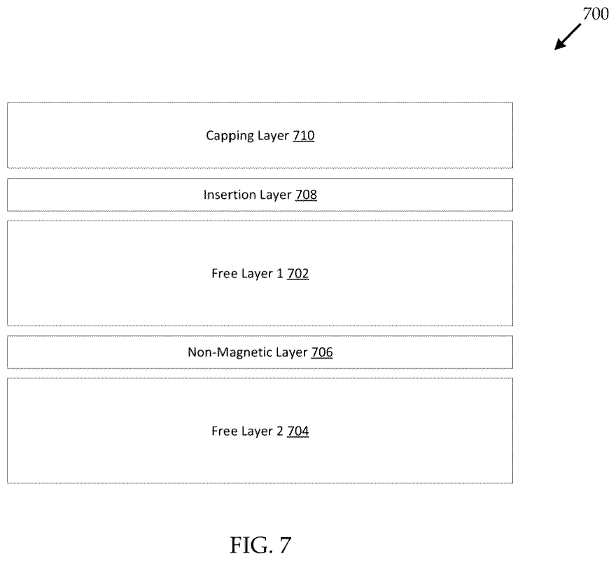

FIG. 7 is an illustration 700 of a third example free layer structure. As shown in FIG. 7, the structure 700 can include both a non-magnetic layer 706 deposited between free layers 602, 604 as well as an insertion layer 708 deposited adjacent to a capping layer 710.

TABLE 1

| | | | Normal- | Normal- |
|---|---|---|---|---|
| | Bst | Hc | ized | ized |
| Free Layer Structure | (easy) | (easy) | Bst | Hc |
| Without Ta or Hf insertion | | | | |
| CoFeB/CoFeHf/Ru | 2.63 | 5.46 | 1.00 | 1.00 |
| With Hf insertion | | | | |
| CoFeB/Hf/CoFeHf/Ru | 2.56 | 4.32 | 0.97 | 0.79 |
| CoFeB/CoFeHf/Hf/Ru | 2.62 | 4.41 | 1.00 | 0.81 |
| CoFeB/0.7Hf/CoFeHf/Hf/Ru | 2.58 | 3.89 | 0.98 | 0.71 |
| With Ta insertion | | | | |
| CoFeB/Ta/CoFeHf/Ru | 2.55 | 3.63 | 0.97 | 0.66 |
| CoFeB/CoFeHf/Ta/Ru | 2.62 | 3.58 | 1.00 | 0.66 |
| CoFeB/0.7Ta/CoFeHf/Ta/Ru | 2.56 | 3.46 | 0.97 | 0.63 |

Table 1 provides example free layer magnetic properties of CoFeB/CoFeHf with or without Ta or Hf insertion after 280C, with 5 hours annealing.

TABLE 2

| | | | Normal- | Normal- |
|---|---|---|---|---|
| | Bst | Hc | ized | ized |
| Film Structure | (easy) | (easy) | Bst | Hc |
| Without Ta insertion | | | | |
| CoFeB/CoFeTa/Ru | 2.19 | 4.27 | 1.00 | 1.00 |
| With Ta insertion | | | | |
| CoFeB/Ta/CoFeTa/Ru | 2.13 | 3.25 | 0.97 | 0.76 |
| CoFeB/CoFeTa/Ta/Ru | 2.19 | 3.33 | 1.00 | 0.78 |
| CoFeB/0.7Ta/CoFeTa/Ta/Ru | 2.12 | 2.42 | 0.97 | 0.57 |

Table 2 provides example free layer magnetic properties of CoFeB/CoFeTa with or without Ta insertion after 280C, with 5 hours annealing.

From Table 1, it can be seen that with a thin Ta or Hf layer insertion, the coercivity of the free layer can be reduced by around 30% with only very minor magnetic moment dilution. The thin Ta or Hf layer can break the crystalline structure influence from a first free layer (CoFeB) and the Ru capping layer on CoFeHf (a second free layer). As a result, a more amorphous CoFeHf free layer with smaller Hc can be obtained.

Applying the same concept from Table 1, the coercivity of CoFeB/CoFeTa free layer can be further reduced with minimal drop in magnetic moment by inserting a thin Ta layer in the free layer or before Ru capping layer, as shown in Table 2. By inserting a thin Hf or Ta layer in CoFeB/CoFeTa (or CoFeHf) free layers, a magnetically soft, anisotropic, and high moment film can be produced. This film structure can be used for next-generation magnetic recording applications. A TMR reader sensor with good device performance can be expected.

A reader with magnetically soft and high flux free layer can provide a high magnetic moment and increased device sensitivity. Further, various methods can further improve the free layer properties by inserting a thin Ta or Hf thin layer between free layer 1 (CoFeB) and free layer 2 (CoFeTa or CoFeHf). Further, the free layer properties can be improved by having a thin Ta or Hf deposited underneath Ru capping layer or depositing the thin Ta or Hf layer in both the free layer and before Ru capping layers. The thin Ta or Hf can reduce the influence of crystalline structure from free layer 1 (CoFeB) and capping layer (Ru) on free layer 2 (CoFeTa or CoFeHf). As a result, an amorphous free layer (CoFeTa or CoFeHf) with low Hc and high Bst can be obtained.

In a first example embodiment, a free layer structure for a tunneling magneto-resistive (TMR) sensor is provided. The free layer structure can include a first free layer, a second free layer, and a non-magnetic layer deposited between the first free layer and the second free layer. The free layer structure can be anisotropic and can have low Hc, high moment, and high dR/R.

In some instances, the first free layer comprises a Cobalt-Iron-Boron (CoFeB) alloy.

In some instances, the second free layer comprises a Cobalt-Iron-Tantalum (CoFeTa) alloy or a Cobalt-Iron-Hafnium (CoFeHf) alloy.

In some instances, the non-magnetic layer comprises any of Hafnium (Hf), Tantalum (Ta), Yttrium (Y), Niobium (Nb), Molybdenum (Mo), Tungsten (W), and Titanium (Ti).

In some instances, a thickness of the non-magnetic layer is less than 2 Angstroms (A) or ranging between 0.2 and 2.5 A.

In some instances, the free layer structure can further include an insertion layer deposited adjacent to the first free layer and a capping layer deposited over the insertion layer. The insertion layer can be configured to reduce an influence of a crystalline structure of the capping layer to the first free layer.

In some instances, the insertion layer comprises any of Hf, Ta, Y, Zr, Nb, Mo, W, Ti. A thickness of the insertion layer can be less than 5 A or ranging between 1 to 5 A.

In some instances, the capping layer comprises Ruthenium (Ru).

In some instances, the first free layer comprises CoFe-xB-y or CoFe-aHf-b, where x is between 10-70 percent of the material (at %), wherein y is between 5-30 at %, a is between 10-70 at %, and wherein b is between 2-20 at %.

In some instances, the free layer structure is configured to be deposited adjacent to a barrier layer that is adjacent to a pin layer. A magnetization direction of the pin layer can be configured to be fixed and a magnetization direction of the free layer is configured to change due to an external magnetic field direction. The barrier layer can be configured to include any of magnesium oxide (MgO), aluminum oxide (AlOx), titanium oxide (TiOx), and/or zinc oxide (ZnOx).

In another example embodiment, a device is provided. The device can include a free layer structure that includes a first free layer, a second free layer, and a non-magnetic layer deposited between the first free layer and the second free layer. The device can also include an insertion layer deposited adjacent to the first free layer, and a capping layer deposited over the insertion layer. The insertion layer can be configured to reduce an influence of a crystalline structure of the capping layer to the first free layer.

In some instances, the first free layer comprises a Cobalt-Iron-Boron (CoFeB) alloy. The second free layer can include a Cobalt-Iron-Tantalum (CoFeTa) alloy or a Cobalt-Iron-Hafnium (CoFeHf) alloy.

In some instances, the non-magnetic layer and the insertion layer comprises any of Hafnium (Hf), Tantalum (Ta), Yttrium (Y), Niobium (Nb), Molybdenum (Mo), Tungsten (W), and Titanium (Ti).

In some instances, a thickness of the non-magnetic layer is less than 2 Angstroms (A) or ranging between 0.2 and 2.5 A. A thickness of the insertion layer can be less than 5 A or ranging between 1 to 5 A.

In some instances, the capping layer comprises Ruthenium (Ru).

In some instances, the first free layer comprises CoFe-xB-y or CoFe-aHf-b, where x is between 10-70 percent of the material (at %), wherein y is between 5-30 at %, a is between 10-70 at %, and wherein b is between 2-20 at %.

In some instances, the free layer structure is configured to be deposited adjacent to a barrier layer that is adjacent to a pin layer. A magnetization direction of the pin layer can be configured to be fixed and a magnetization direction of the free layer is configured to change due to an external magnetic field direction. The barrier layer can be configured to include any of magnesium oxide (MgO), aluminum oxide (AlOx), titanium oxide (TiOx), and/or zinc oxide (ZnOx).

In another example embodiment, a method of manufacturing a free layer structure for a tunneling magneto-resistive (TMR) sensor is provided. The method can include depositing a non-magnetic layer between a first free layer and a second free layer. The non-magnetic layer can include Tantalum (Ta) or Hafnium (Hf). The first free layer and second free layer can include any of a Cobalt-Iron-Boron (CoFeB) alloy, a Cobalt-Iron-Tantalum (CoFeTa) alloy, and a Cobalt-Iron-Hafnium (CoFeHf) alloy. The method can also include depositing a barrier layer adjacent to the free layer structure. The method can also include depositing a pin layer adjacent to the barrier layer.

In some instances, the method can also include depositing an insertion layer adjacent to the first free layer and depositing a capping layer over the insertion layer. The insertion layer can be configured to reduce an influence of a crystalline structure of the capping layer to the first free layer.

In some instances, the insertion layer comprises any of Hf, Ta, Y, Zr, Nb, Mo, W, Ti, and wherein a thickness of the insertion layer is less than 5 A or ranging between 1 to 5 A.

It will be understood that terms such as “top,” “bottom,” “above,” “below,” and x-direction, y-direction, and z-direction as used herein as terms of convenience that denote the spatial relationships of parts relative to each other rather than to any specific spatial or gravitational orientation. Thus, the terms are intended to encompass an assembly of component parts regardless of whether the assembly is oriented in the particular orientation shown in the drawings and described in the specification, upside down from that orientation, or any other rotational variation.

It will be appreciated that the term “present invention” as used herein should not be construed to mean that only a single invention having a single essential element or group of elements is presented. Similarly, it will also be appreciated that the term “present invention” encompasses a number of separate innovations, which can each be considered separate inventions. Although the present invention has been described in detail with regards to the preferred embodiments and drawings thereof, it should be apparent to those skilled in the art that various adaptations and modifications of embodiments of the present invention may be accomplished without departing from the spirit and the scope of the invention. Accordingly, it is to be understood that the detailed description and the accompanying drawings as set forth hereinabove are not intended to limit the breadth of the present invention, which should be inferred only from the following claims and their appropriately construed legal equivalents.

What is claimed is:

1. A free layer structure for a tunneling magneto-resistive (TMR) sensor, the free layer structure comprising:
a first free layer;
a second free layer; and
a non-magnetic layer deposited between the first free layer and the second free layer, wherein the free layer structure is anisotropic and has a low coercive magnetic field strength of around 4 of less Oersteds (Oe), a high magnetic flux density of around 2 or more nanowebers (nWb), and a high magnetoresistance (MR) ratio of around 120% or more dR/R at a RA0.3.

2. The free layer structure of claim 1, wherein the first free layer comprises a Cobalt-Iron-Boron (CoFeB) alloy.

3. The free layer structure of claim 1, wherein the second free layer comprises a Cobalt-Iron-Tantalum (CoFeTa) alloy or a Cobalt-Iron-Hafnium (CoFeHf) alloy.

4. The free layer structure of claim 1, wherein the non-magnetic layer comprises any of Hafnium (Hf), Tantalum (Ta), Yttrium (Y), Niobium (Nb), Molybdenum (Mo), Tungsten (W), and Titanium (Ti).

5. The free layer structure of claim 1, wherein a thickness of the non-magnetic layer is less than 2 Angstroms (A) or ranging between 0.2 and 2.5 A.

6. The free layer structure of claim 1, further comprising:
an insertion layer deposited adjacent to the first free layer; and
a capping layer deposited over the insertion layer, wherein the insertion layer is configured to reduce an influence of a crystalline structure of the capping layer to the first free layer.

7. The free layer structure of claim 6, wherein the insertion layer comprises any of Hf, Ta, Y, Zr, Nb, Mo, W, Ti, and wherein a thickness of the insertion layer is less than 5 A or ranging between 1 to 5 A.

8. The free layer structure of claim 6, wherein the capping layer comprises Ruthenium (Ru).

9. The free layer structure of claim 1, wherein the first free layer comprises CoFe-xB-y or CoFe-aHf-b, where x is between 10-70 percent of the material (at %), wherein y is between 5-30 at %, a is between 10-70 at %, and wherein b is between 2-20 at %.

10. The free layer structure of claim 1, wherein the free layer structure is configured to be deposited adjacent to a barrier layer that is adjacent to a pin layer, wherein a magnetization direction of the pin layer is configured to be fixed and a magnetization direction of the free layer is configured to change due to an external magnetic field direction, and wherein the barrier layer is configured to include any of magnesium oxide (MgO), aluminum oxide (AlOx), titanium oxide (TiOx), and/or zinc oxide (ZnOx).

11. A device comprising:
a free layer structure that includes:
a first free layer;
a second free layer; and
a non-magnetic layer deposited between the first free layer and the second free layer;
an insertion layer deposited adjacent to the first free layer; and
a capping layer deposited over the insertion layer, wherein the insertion layer is configured to reduce an influence of a crystalline structure of the capping layer to the first free layer.

12. The device of claim 11, wherein the first free layer comprises a Cobalt-Iron-Boron (CoFeB) alloy, and wherein the second free layer comprises a Cobalt-Iron-Tantalum (CoFeTa) alloy or a Cobalt-Iron-Hafnium (CoFeHf) alloy.

13. The device of claim 11, wherein the non-magnetic layer and the insertion layer comprises any of Hafnium (Hf), Tantalum (Ta), Yttrium (Y), Niobium (Nb), Molybdenum (Mo), Tungsten (W), and Titanium (Ti).

14. The device of claim 11, wherein a thickness of the non-magnetic layer is less than 2 Angstroms (A) or ranging between 0.2 and 2.5 A, and wherein a thickness of the insertion layer is less than 5 A or ranging between 1 to 5 A.

15. The device of claim 11 wherein the capping layer comprises Ruthenium (Ru).

16. The device of claim 11, wherein the first free layer comprises CoFe-xB-y or CoFe-aHf-b, where x is between 10-70 percent of the material (at %), wherein y is between 5-30 at %, a is between 10-70 at %, and wherein b is between 2-20 at %.

17. The device of claim 11, wherein the free layer structure is configured to be deposited adjacent to a barrier layer that is adjacent to a pin layer, wherein a magnetization direction of the pin layer is configured to be fixed and a magnetization direction of the free layer is configured to change due to an external magnetic field direction, and wherein the barrier layer is configured to include any of magnesium oxide (MgO), aluminum oxide (AlOx), titanium oxide (TiOx), and/or zinc oxide (ZnOx).

18. A method of manufacturing a free layer structure for a tunneling magneto-resistive (TMR) sensor, the method comprising:
depositing a non-magnetic layer between a first free layer and a second free layer, wherein the non-magnetic layer comprises Tantalum (Ta) or Hafnium (Hf), and wherein the first free layer and second free layer comprises any of a Cobalt-Iron-Boron (CoFeB) alloy, a Cobalt-Iron-Tantalum (CoFeTa) alloy, and a Cobalt-Iron-Hafnium (CoFeHf) alloy;
depositing a barrier layer adjacent to the free layer structure; and
depositing a pin layer adjacent to the barrier layer.

19. The method of claim 18, further comprising:
depositing an insertion layer adjacent to the first free layer, and
depositing a capping layer over the insertion layer, wherein the insertion layer is configured to reduce an influence of a crystalline structure of the capping layer to the first free layer.

20. The method of claim 18, wherein the insertion layer comprises any of any of Hafnium (Hf), Tantalum (Ta), Yttrium (Y), Niobium (Nb), Molybdenum (Mo), Tungsten (W), and Titanium (Ti), and wherein a thickness of the insertion layer is less than 5 A or ranging between 1 to 5 A.
